(19) United States
(12) Patent Application Publication
(10) Pub. No.: US 2010/0246066 A1
(43) Pub. Date: Sep. 30, 2010

(54) HEAD SLIDER, STORAGE DEVICE, AND METHOD OF MANUFACTURING HEAD SLIDER

(75) Inventors: Yoshiharu KASAMATSU, Ome-shi (JP); Takayuki MUSASHI, Fujisawa-shi (JP); Keiji WATANABE, Kawasaki (JP)

Correspondence Address: KNOBBE MARTENS OLSON & BEAR LLP, 2040 MAIN STREET, FOURTEENTH FLOOR, IRVINE, CA, 92614, US

(73) Assignee: TOSHIBA STORAGE DEVICE CORPORATION, Tokyo (JP)

(21) Appl. No.: 12/790,228

(22) Filed: May 28, 2010

Related U.S. Application Data
(63) Continuation of application No. PCT/JP2007/073223, filed on Nov. 30, 2007.

(51) Int. Cl. G11B 5/60; B05D 5/12; C23C 14/28

(52) U.S. Cl. 360/235.4; 427/58; 427/595; G9B/5.229

(57) ABSTRACT

According to one embodiment, a head slider includes an element unit formed by lamination on a substrate, a cut surface formed by cutting the substrate, an air-bearing surface configured to face a recording medium when in flight, a protective layer configured to protect at least the air-bearing surface of the element unit, and a coating layer configured to cover at least the cut surface exclusive of the air-bearing surface of the element unit. An outermost surface of the air-bearing surface is formed of the protective layer in the element unit at the least.

### CROSS REFERENCE TO RELATED APPLICATIONS

This is a Continuation Application of PCT Application No. PCT/JP2007/073223, filed Nov. 30, 2007, which was published under PCT Article 21(2) in Japanese.

### FIELD

Embodiments described herein relate generally to a head slider comprising a head element for recording and reproduction, a storage device provided with the same, and a method of manufacturing the head slider.

### BACKGROUND

In general, a head slider is mounted with a magnetic head element used for recording and reproduction in a magnetic disk drive and configured to fly with a fixed gap above the surface of the magnetic disk.

Manufacturing processes for a modern head slider include a process in which a ceramic substrate of, for example, alumina-titanium carbide, formed with a large number of magnetic head elements on its front face, is cut into row bars with the head elements arranged in a row, and a process in which each row bar is further segmented into head sliders each formed with a single magnetic head element. In the process for segmenting each row bar into the individual head sliders, cracks may occur in cut surfaces. While the magnetic disk drive incorporated with the head sliders is operating, the cracks may cause separation or chipping of the sliders, so that fine ceramic powder or particles may drop onto the magnetic disk. If the head sliders pass above the dropped particles, the particles may become jammed between the disk surface and sliders. Consequently, errors may occur in read or write signals, and in addition, head crash may be caused.

Conventionally, in order to prevent separation of ceramic particles, ultrasonic cleaning is positively performed before the head sliders are assembled. Recently, a proposal has been made to coat the entire surface of each individual head slider with a fluorocarbon resin, as described in, for example, Jpn. Pat. Appln. KOKAI Publication No. 2002-7481. Since the entire surface of each head slider is coated with the resin, however, a magnetic spacing loss is caused in the magnetic head element by a thick film of the resin, thereby adversely affecting the sensitivity of the head element. If the resin film is made thinner to reduce the magnetic spacing loss, moreover, particulate dust cannot be fully prevented from dropping off.

### BRIEF DESCRIPTION OF THE DRAWINGS

FIG. 1 is an exemplary perspective view showing a magnetic disk drive to which a head slider according to a first embodiment is applied;

FIG. 2 is an exemplary perspective view showing a head suspension assembly on which the head slider is mounted;

FIG. 3 is an exemplary diagram illustrating how the head slider is cut out in a head slider manufacturing process;

FIG. 4 is an exemplary perspective view showing the head slider according to the first embodiment;

FIGS. 5A, 5B, and 5C are exemplary sectional views individually showing resin coating processes for the head slider of the first embodiment;

FIG. 6 is an exemplary perspective view showing a head slider according to a second embodiment;

FIGS. 7A, 7B, 7C, and 7D are exemplary sectional views individually showing resin coating processes for the head slider of the second embodiment;

FIG. 8 is an exemplary flowchart schematically showing resin coating processes for a head slider according to a third embodiment; and

FIGS. 9A and 9B are exemplary sectional views individually showing processes in which a coating layer on a head element of the head slider is removed by grinding.

### DETAILED DESCRIPTION

In general, according to one embodiment, a head slider comprises: an element unit formed by lamination on a substrate; a cut surface formed by cutting the substrate; an air-bearing surface configured to face a recording medium when in flight; a protective layer configured to protect at least the air-bearing surface of the element unit; and a coating layer configured to cover at least the cut surface exclusive of the air-bearing surface of the element unit. An outermost surface of the air-bearing surface is formed of the protective layer in the element unit at the least.

A head slider, magnetic disk drive, and method of manufacturing the head slider according to each of embodiments will now be described in detail with reference to the accompanying drawings.

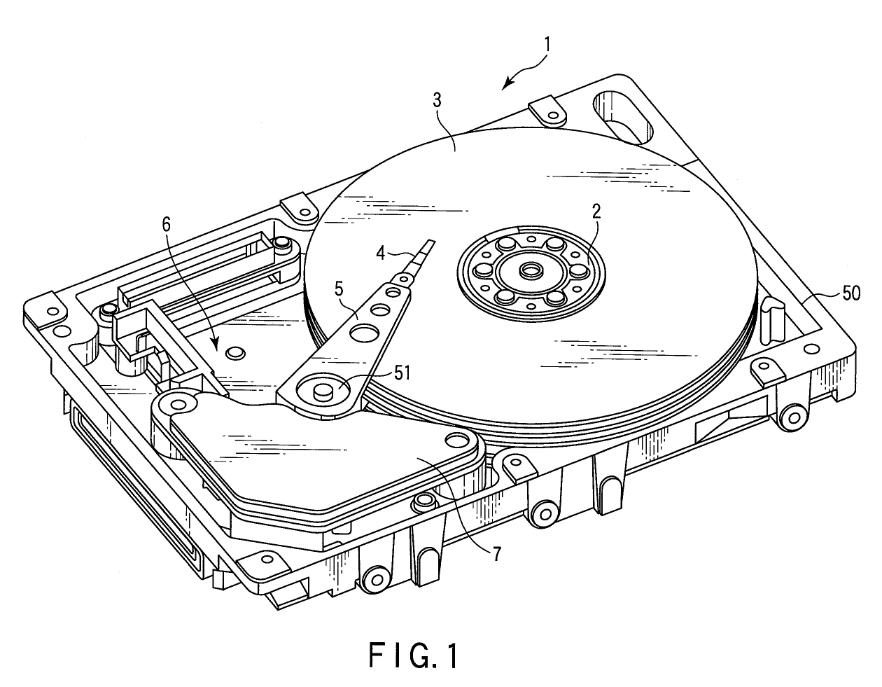

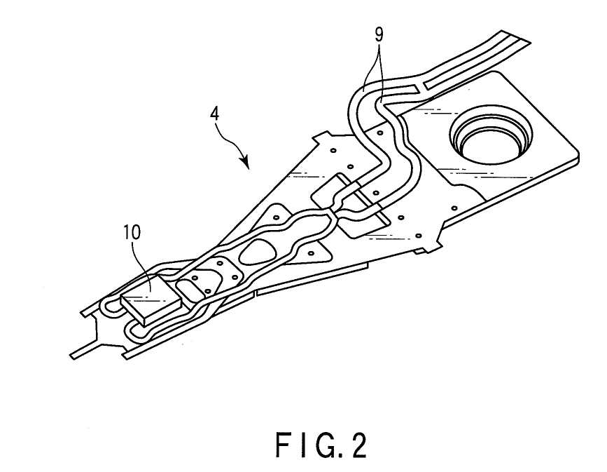

FIG. 1 is a perspective view showing a hard disk drive (HDD) 1 as a magnetic storage device according to a first embodiment, and FIG. 2 is a perspective view showing a head suspension assembly of the HDD. As shown in FIGS. 1 and 2, the HDD 1 comprises a spindle 2, magnetic disks 3 for use as magnetic recording media, head slider 10, head suspension 4, and actuator arm 5. The spindle 2 is mounted on a base 50 and rotates at high speed. The magnetic disks 3 are mounted at equal intervals on the spindle motor 2. The head slider 10 is formed with head elements that write or read information to or from the disk 3. The head suspension 4 holds the head slider 10. The actuator arm 5 holds the head suspension 4. The arm 5 is disposed on the base 50 so as to be pivotable about a support portion 51. The arm 5 is driven at high speed by a voice coil motor 7 and moves the head elements radially relative to the magnetic disk 3. The spindle motor 2 constitutes a mechanical unit that supports and rotates the disk 3.

The HDD 1 comprises an electric circuit unit 6 including a write/read circuit, control circuit, etc. The write/read circuit processes information to be written to and read from the magnetic disk 3. The control circuit controls the operation of the voice coil motor 7. If the head slider used is configured for dynamic flying height (DFH) control, the electric circuit unit 6 also controls a current to be passed through a heater for DFH control.

FIG. 2 shows that side of the head suspension 4 which faces the magnetic disk 3. The head slider 10 on which the head elements are integrally formed is supported on the head suspension 4. The head elements of the head slider 10 are electrically connected to the electric circuit unit 6 by printed conductors 9 disposed on the suspension 4.

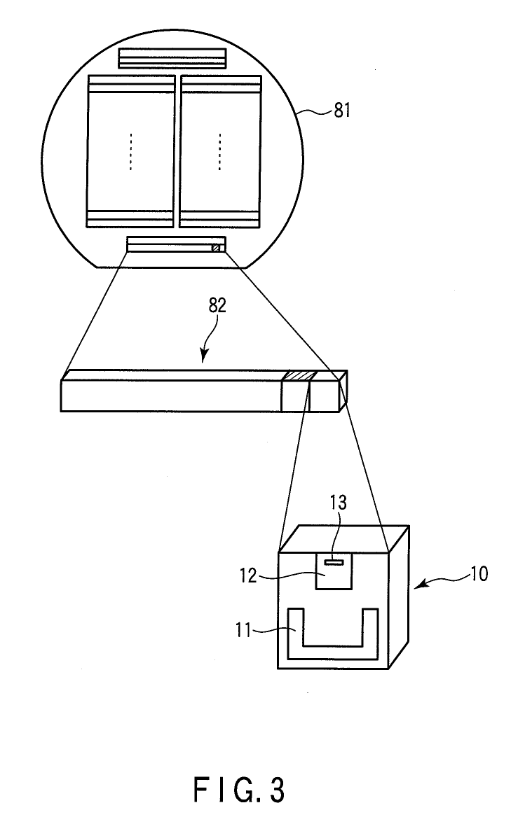

FIG. 3 is a diagram typically showing a manufacturing process for the head slider according to the present embodiment. In manufacturing the head slider 10, a large number of head elements, such as giant-magnetoresistive-effect (GMR) heads, are formed on the entire surface of a ceramic substrate 81 that is formed of, for example, alumina-titanium carbide (Al₂O₃—TiC). Then, the ceramic substrate 81 with the head elements formed thereon is cut into row bars 82 each comprising a plurality of magnetic head elements arranged in a row.

Subsequently, each row bar 82 is polished so that the height of a thin-film magnetoresistive layer of each head element or gap height has a predetermined value. Then, after each cut surface of the row bar 82 is worked into the shape of an air-lubrication surface such as a rail, a protective layer for protecting the lubrication surface including the head element is formed. Finally, the row bar 82 is segmented into pieces, whereupon head sliders 10 are formed each comprising a head element 13 and rails.

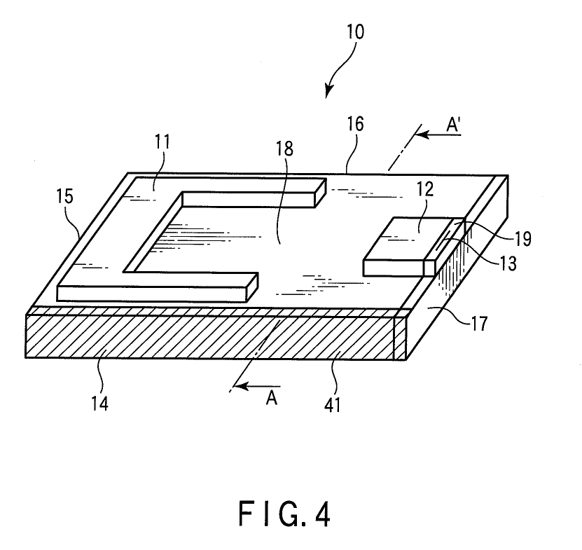

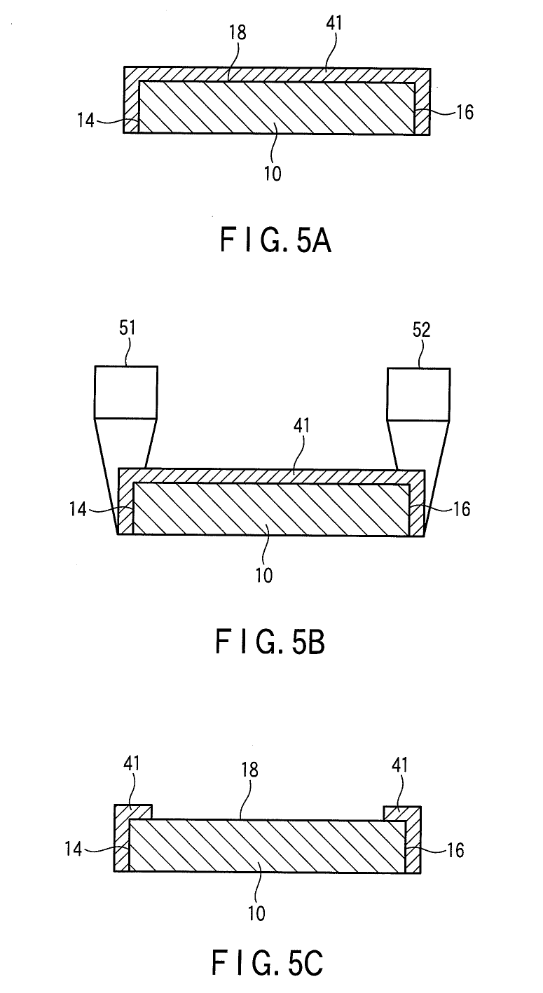

The head slider according to the first embodiment will be described with reference to FIGS. 4 and 5. FIG. 4 shows the head slider of the first embodiment coated with a resin, and FIGS. 5A to 5C individually show resin coating processes for the head slider.

FIG. 4 shows an air-bearing surface 18 of the head slider 10 that faces the magnetic disk 3 for use as a storage medium. In order to obtain a predetermined flying height, the air-bearing surface of the head slider 10 is formed with an inlet-side rail 11 located on the air inlet side and an outlet-side rail 12 on the air outlet side. The head element 13 is formed on the outlet-side rail 12. A protective layer 19 is formed on that surface of the head element 13 on the side of the air-bearing surface 18 and forms an outermost surface. The protective layer 19 may be one that covers the entire air-bearing surface 18. The shapes and locations of the rails 11 and 12 of the head slider or those of the head element are not limited.

In manufacture, a wafer is cut into the row bars and each row bar into pieces so that the head slider 10 is obtained as a single piece, such as the one shown in FIG. 4. In cutting the row bars out of the wafer, side surfaces that form the air-bearing surface 18 and its reverse side, individually, are regarded as cut surfaces. In cutting the pieces out of each row bar, side surfaces 14 and 16 are regarded as cut surfaces. Further, an air-inlet end surface 15 is also polished. Since an air-outlet end surface 17 is an aluminum surface, separation or dropping off of AlTic particles does not need to be considered. Thus, all the surfaces of the head slider 10 except the air-outlet end surface 17 are cut surfaces.

In the present embodiment, the side surface that forms the air-bearing surface 18 is formed by cutting based on ion trimming of the cut surfaces. In some cases, the air-bearing surface 18 may be polished. In order to prevent ceramic particles from dropping off, in the present embodiment, moreover, only the side surfaces 14 and 16 of the head slider 10 where separation of ceramic particles occurs most frequently are coated with a resin, whereupon a coating layer 41 is formed. Consequently, the head element 13 of the head slider 10 is not resin-coated. A better effect can be obtained if the air-inlet end surface 15 of the head slider 10 is resin-coated.

FIGS. 5A to 5C schematically show changes of cross section A-A′ of the head slider 10 in the resin coating processes.

First, a fluorocarbon resin, such as Fomblin-725 (Trademark), is applied to the entire surface of the head slider 10 in the form of a head gimbal assembly (HGA) mounted on the head suspension. As shown in FIG. 5A, the resin coating layer is formed on the air-bearing surface 18 and side surfaces 14 and 16 of the head slider 10. The fluorocarbon resin may also be applied to the surface of the head slider 10 opposite to the air-bearing surface 18. Since the head slider 10 is in the form of the HGA when it is coated with the fluorocarbon resin according to the present embodiment, however, the resin is not spread on the surface opposite to the air-bearing surface 18.

Although a lubricant for storage media is available as a suitable fluorocarbon resin to be applied, the present invention is not limited to this. The fluorocarbon resin used was diluted to a concentration of 0.1% by weight with a fluorine-based solvent, such as Vertrel (Trademark). The head slider 10 in the HGA was dipped in a dip tank filled with the fluorocarbon resin and then pulled up at a speed of 300 mm/min. The film of the fluorocarbon resin spread on the head slider 10 was about 1 to 2 nm. The applied resin film thickness can be changed by adjusting the resin concentration and the pull-up speed of the head slider 10. Preferably, the film thickness should be suitably changed depending on the slider or end face shape.

Then, the side surfaces 14 and 16 of the head slider 10 are irradiated from above with ultraviolet laser beams of wavelength 200 nm from sources of ionizing radiation, e.g., ultraviolet laser sources 51 and 52, as shown in FIG. 5B. The side surfaces 14 and 16 are scanned with the laser beams from the laser sources 51 and 52 from the inlet end side to the outlet end side. Consequently, the resin coating layer 41 formed on the side surfaces 14 and 16 of the head slider 10 is cured and firmly adheres to the slider 10. That other part of the coating layer 41 which is not irradiated with the ultraviolet laser beams remains uncured. The scanning by means of the ultraviolet laser sources 51 and 52 may be performed either by oscillation of the laser beams or movement of the head slider 10. Available ionizing radiation for curing the resin coating layer 41 includes far ultraviolet rays, vacuum ultraviolet rays, extreme ultraviolet rays, X-rays, ion beams, etc.

Then, the head slider 10 is dipped in the fluorine based solvent (e.g., Vertrel (Trademark)) and pulled up. Thereupon, that part of the coating layer 41 which is not irradiated with the ultraviolet laser beams and uncured is dissolved in the solvent and removed. FIG. 5C shows a cross section of the head slider 10 from which the unnecessary part of the resin coating layer 41 is removed. The resin coating layer 41 remains on the side surfaces 14 and 16 of the head slider 10.

In the present embodiment, the resin coating layer is formed on and removed from the head slider 10 that is incorporated in the HGA. Alternatively, however, the resin coating layer may be formed on and removed from each head slider in the form of a single piece in the aforementioned manner before the HGA is assembled.

In curing those parts of the resin coating layer 41 which are applied to the other side surfaces 15 and 17, two laser sources for applying laser beams to the side surfaces 15 and 17 may be additionally provided. Alternatively, the head slider 10 may be horizontally rotated for 90° so that laser beams from the ultraviolet laser sources 51 and 52 can be applied to the side surfaces 15 and 17. Further, four laser sources may be arranged so as to irradiate four end faces, individually.

According to the head slider of the HDD of the first embodiment and a method of manufacturing the head slider, the coating layer is formed only on the side surfaces of the slider as the cut surfaces and not on the air-bearing surface, so that the head element is not covered by the coating layer. Thus, the coating layer on the side surfaces of the head slider can be made thicker. If the coating layer is made thicker, the resin can easily infiltrate cracks in the cut surfaces by capillary action. The resin having saturated the cracks acts as a strong adhesive when it is cured. Consequently, chipping can be prevented more effectively, and particles can be effectively prevented from dropping off the head slider. Since the head element is not coated, moreover, it can be brought sufficiently close to the magnetic disk surface, so that a magnetic space loss can be prevented.

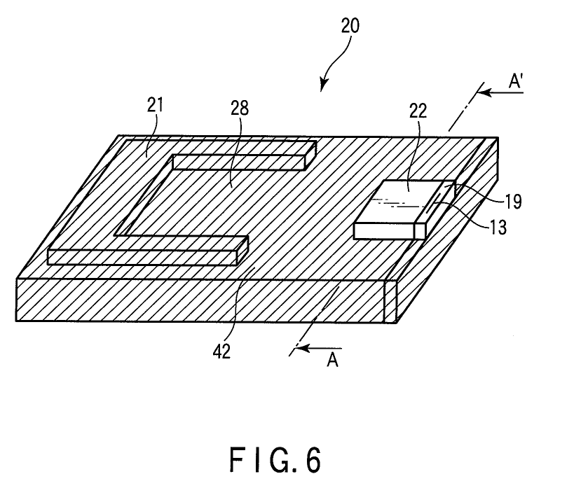

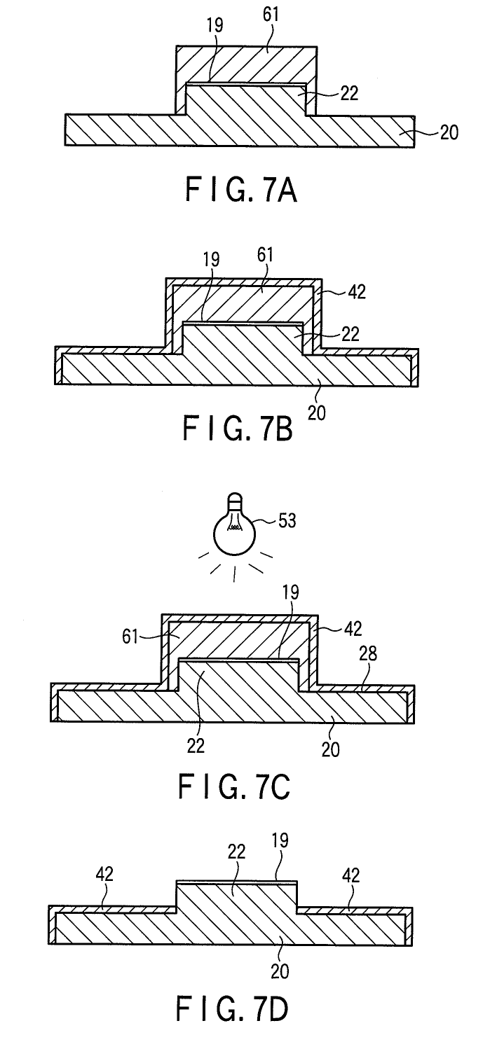

A head slider of an HDD according to a second embodiment will be described with reference to FIGS. 6 and 7. FIG. 6 shows the head slider of the second embodiment coated with a resin, and FIGS. 7A to 7D individually show resin coating processes for the head slider.

As shown in FIG. 6, a head slider 20 comprises an air-bearing surface 28, which faces a magnetic disk for use as a storage medium. The air-bearing surface 28 is formed with an air-inlet-side rail 21 and outlet-side rail 22. A head element 23 is formed on the outlet-side rail 22. A protective layer 19 is formed on that surface of the head element 23 on the side of the air-bearing surface 28 and forms an outermost surface. The protective layer 19 may be formed so as to cover the entire air-bearing surface 28. Further, the entire body of the head slider 20 except the outlet-side rail 22 on which the head element 23 is formed is coated with a resin, whereby a resin coating layer 42 is formed. The coating layer 42 is formed on the entire area of the air-bearing surface 28 except the outlet-side rail 22 and four side surfaces that adjoin the air-bearing surface.

FIGS. 7A to 7D are views illustrating changes of cross section A-A′ of the head slider 10 in the resin coating processes.

First, a resist pattern 61 of a photosensitive resin is formed so as to cover the outlet-side rail 22 on which the head element 23 (FIG. 6) of the head slider 20 is formed, as shown in FIG. 7A. A positive resist is used for the resist pattern, of which parts irradiated with ionizing radiation are dissolved and removed. In the present embodiment, the resist pattern 61 is formed on the head slider in the form of a single piece before the formation of an HGA for the reason that the resist pattern can be easily aligned. However, the resist pattern may also be formed on the head slider 20 after the HGA is assembled.

Then, a fluorocarbon resin, such as Fomblin-725 (Trademark), diluted to a concentration of 0.1% by weight with a fluorine-based solvent, such as Vertrel (Trademark), was applied to the entire surface of the head slider 20 on which the resist pattern 61 covering the outlet-side rail 22 was formed. Specifically, the head slider 20 was dipped in a dip tank filled with the fluorocarbon resin and then pulled up, whereby the resin was applied to the entire surface of the slider. The film thickness of the applied resin can be changed by adjusting the resin concentration and the pull-up speed of the head slider 20. Preferably, the film thickness should be suitably changed depending on the slider or end face shape. FIG. 7B shows a cross section of the head slider in a stage after the application of the resin is finished so that the coating layer 42 is formed on the entire surface. The resin may be applied to a rail forming surface (not shown) of the head slider 20, that is, the side opposite to the air-bearing surface.

Then, the entire surface of the head slider 20 is irradiated with ionizing radiation, which dissolves the resist pattern 61, from an ionizing radiation source 53 that is located opposite the air-bearing surface 28 of the head slider. The applied ionizing radiation may be the same as that used in the first embodiment. While the resin irradiated with the ionizing radiation is solidified, the resist pattern 61 is dissolved by the ionizing radiation that is transmitted through the coating layer 42 and reaches the resist pattern. In the second embodiment, unlike the first embodiment, the resin does not need to be partially solidified, so that the entire surface of the head slider should only be irradiated with ionizing radiation without constricting the radiation for scanning.

Thereafter, the head slider 20 is dipped in the fluorine-based solvent (e.g., Vertrel (Trademark)) and pulled up. Thereupon, the resin that covers the outlet-side rail formed on the resist pattern 61 is removed together with the resist pattern. Thus, the coating layer 42 is formed on the entire surface of the head slider 20 except the outlet-side rail 22 on which the head element 23 is formed, as shown in FIG. 7D.

In the second embodiment, a chip cut out of a row bar is resin-coated. This is done in consideration of the ease of resist patterning. If the resist patterning can be performed even after the HGA is assembled, the second embodiment is also applicable to a head slider incorporated in the HGA.

The head slider 20 of the second embodiment, like the head slider 10 of the first embodiment, is designed so that the resin is not spread on the head element. Therefore, the resin coating layer can be made thick at the other part. Since the head element is not coated, moreover, the slider surface can be brought sufficiently close to the magnetic disk surface, so that a magnetic space loss can be prevented. Since the air-bearing surface can also be covered by the coating layer, furthermore, pitching of the head slider can be prevented more effectively.

A third embodiment relates to a head slider configured for dynamic flying height (DFH) control. The DFH control is a technique for correcting a change in the flying height of the head slider caused by the environmental change of a magnetic storage device. A heater coil is embedded around a head element unit, the temperature of the storage device is monitored, and a current is passed through the heater. By doing this, a magnetic head is thermally expanded to correct the change in the flying height of the slider. According to the head slider based on DFH control, the magnetic spacing is further reduced, so that a coating layer on the element unit absolutely needs to be removed.

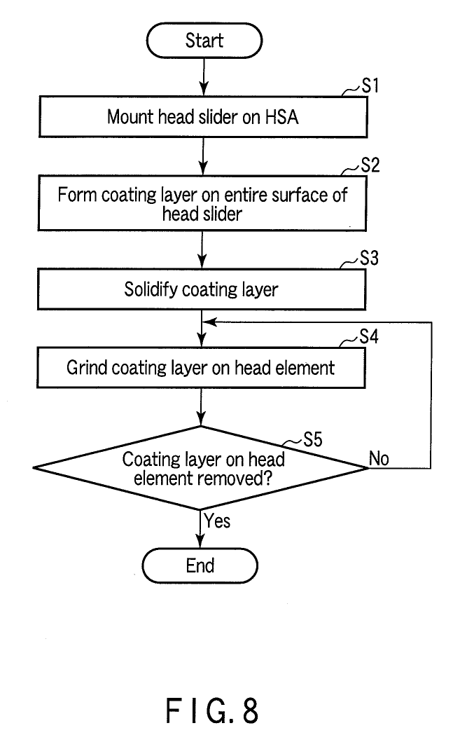

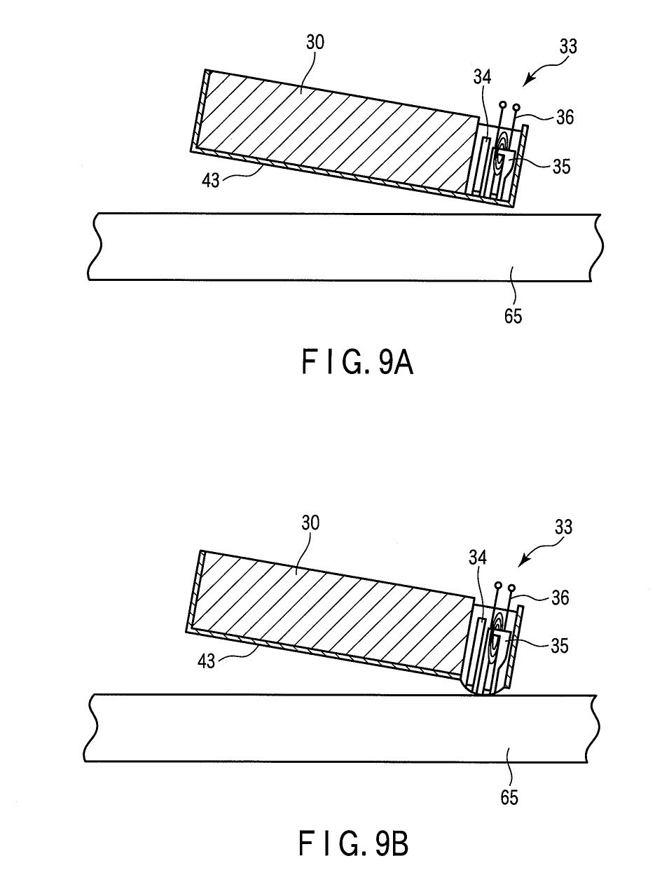

The head slider of an HDD according to the third embodiment will be described with reference to FIGS. 8 and 9. FIG. 8 is a flowchart showing an outline of resin coating processes for the head slider of the third embodiment.

First, a head suspension assembly (HSA) is assembled by mounting the head slider configured for DFH control on a suspension and making wiring for energizing the heater coil around the head element unit (S1). The HSA is a version of a head gimbal assembly (HGA) that is further provided with conductors for a head element.

The head slider of the assembled HSA is dipped in a fluorocarbon resin solution and pulled up at such a speed that a resin coating layer with a desired thickness can be formed on the entire surface of the head slider (S2). As in the first and second embodiments, the fluorocarbon resin solution is prepared by diluting a fluorocarbon resin, such as Fomblin-725 (Trademark), to a concentration of 0.1% by weight with a fluorine-based solvent, such as Vertrelv (Trademark). In Step S2, the resin coating layer is formed on the entire surface of the head slider.

Then, the entire surface of the head slider is irradiated with ionizing radiation, such as ultraviolet rays, whereby the applied fluorocarbon resin is solidified (S3).

Then, in Step S4, the resin having once solidified and adhered to the head element is scraped off by grinding. A spin stand available for the inspection and evaluation of head elements and magnetic media is used to grind the solidified resin on the head element. The spin stand is configured to support a magnetic disk and a magnetic head opposite to each other. The spin stand comprises a spindle motor, which rotates the disk at an arbitrary speed, and a positioning device, which positions the mounted head on the disk. A dummy medium for grinding the solidified resin is disposed in place of the magnetic disk on the spin stand, and the HSA is mounted so that the head slider covered by the resin to be ground faces the dummy medium.

FIGS. 9A and 9B show relationships between a head slider 30 mounted on the spin stand and a dummy medium 65, and illustrates processes in which a coating layer on a head element of the head slider is removed by grinding.

A head element 33 integrally formed on the head slider 30 comprises a read head 34, write head 35, and heater 36. The resin spread on the surface of the head slider 30 is solidified, thereby forming a coating layer 43. As shown in FIG. 9A, the coating layer 43 is formed on the head element 33 so as to cover its surface that faces the dummy medium 65.

After the dummy medium 65 is then rotated, as shown in FIG. 9B, a current is passed through the heater 36 for DFH control so that the head element 33 is caused to project toward the dummy medium 65 by means of thermal expansion of the element by resistance heating. The projection length of the head element 33 can be controlled based on the amount of the current that flows through the heater 36. As the head element 33 projects toward the dummy medium 65, it contacts the medium 65, and the coating layer 43 on the element 33 is chipped and removed by the rapidly rotating medium 65.

In order to remove the resin efficiently, the surface of the dummy medium 65 should preferably be shaped so that the resin on the head slider can easily wear. For example, the surface of the dummy medium 65 should be adjusted so that its roughness based on an arithmetic average roughness R is 0.5 nm or more and the lubricant film thickness is about 1.5 nm or less.

In Step S5, it is determined whether or not the coating layer 43 on the head element 33 is removed. Whether or not the coating layer 43 is removed is determined by detecting an acoustic emission (AE) output. The resin can be determined to have been removed if there is no AE output. Alternatively, the back of the head slider 30 may be irradiated with a laser beam, and vibration of the head slider may be detected by means of a Laser Doppler Velocimeter (LDV). In this case, the resin can be determined to have been removed to entirely expose a protective film of the head element when the vibration is removed.

Before the coating layer on the head element is determined to have been removed, the grinding process of Step S4 is continued. If the coating layer on the head element is determined to have been removed in Step S5, this process is terminated.

In the head slider of the third embodiment, like those of the first and second embodiments, the coating layer does not exist on the head element 33. Therefore, the resin coating layer 43 can be made thick at the other part, so that chipping can be prevented more effectively. Since the head element 33 is not coated, moreover, the head slider surface can be brought sufficiently close to the magnetic disk surface, so that a magnetic space loss can be prevented. According to the head slider based on DFH control, in particular, the magnetic spacing is reduced, so that the removal of the coating layer on the head element produces a great effect. Since the coating layer is formed at the part other than that part on the head element which is removed, moreover, the prevention of chipping produces the greatest effect.

In the example described above, the heater 36 for DFH control is energized to cause thermal expansion by resistance heating so that the head element 33 projects toward the surface of the dummy medium 65. Alternatively, however, a current may be passed through the write head 35 so that the head 35 can serve as a heater. Specifically, the head element unit can also be expanded to project toward the medium surface by subjecting the write head 35 to resistance heating. Thus, the coating layer spread on the head element 33 can also be removed by passing a current through the write head 35. The third embodiment is also applicable to a head slider that is not provided with a heater for DFH control.

The head slider configured for DFH control can be manufactured by the method of the first or second embodiment, not that of the third embodiment. In this case, the magnetic spacing is reduced, so that the removal of the coating layer on the head element produces a great effect.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A head slider comprising:
an element unit formed by lamination on a substrate;
a cut surface formed by cutting the substrate;
an air-bearing surface configured to face a recording medium during a flight;
a protective layer configured to protect the air-bearing surface of the element unit; and
a coating layer configured to cover the cut surface exclusive of the air-bearing surface of the element unit,
wherein an outermost surface of the air-bearing surface comprises the protective layer.

2. The head slider of claim 1, further comprises a heater configured to cause the element unit to expand.

3. A storage device comprising:
a disk recording medium;
a mechanical unit configured to rotate the recording medium;
a head slider comprising an element unit;
a suspension configured to support the element unit; and
a rotatable actuator arm configured to support the suspension,
wherein the head slider comprises the element unit formed by lamination on a substrate, a cut surface formed by cutting the substrate, an air-bearing surface configured to face a recording medium during a flight, a protective layer configured to protect the air-bearing surface of the element unit, and a coating layer configured to cover the cut surface exclusive of the air-bearing surface of the element unit,
wherein an outermost surface of the air-bearing surface comprises the protective layer.

4. The storage device of claim 3, wherein the head slider comprises a heater configured to cause the element unit to expand.

5. A method of manufacturing a head slider which comprises an element unit formed by lamination on a substrate, a cut surface formed by cutting the substrate, an air-bearing surface configured to face a medium during a flight, and a coating layer, the method comprising:
forming the coating layer on the air-bearing surface and on the cut surface of the head slider; and
removing the coating layer on the air-bearing surface of the element unit.

6. The method of claim 5, wherein the head slider comprises a heater configured to cause the element unit to expand.

7. The method of claim 5, further comprising:
patterning the air-bearing surface with a resist before the coating;
curing the coating layer by irradiating the coating layer with ionizing radiation after the coating; and
removing the resist and the coating layer on the resist.

8. The method of claim 5, further comprising:
curing the coating layer by irradiating the cut surface with ionizing radiation after the coating; and
removing that part of the coating layer which is not hardened by the curing.

9. The method of claim 5, further comprising:
curing the coating layer by irradiating the coating layer with ionizing radiation after the coating;
supporting the head slider by a suspension;
causing the head slider to fly above a rotating grinding substrate;
energizing the element unit to cause the element unit to expand; and
removing the coating layer on the air-bearing surface of the element unit by the grinding substrate.

10. The method of claim 6, further comprising:
curing the coating layer by irradiating the coating layer with ionizing radiation after the coating;
supporting the head slider by a suspension;
causing the head slider to fly above a rotating grinding substrate;
energizing the heater to cause the element unit to project; and
removing the coating layer on the air-bearing surface of the element unit by the grinding substrate.
